(19) United States
(12) Patent Application Publication
(10) Pub. No.: US 2019/0043673 A1
(43) Pub. Date: Feb. 7, 2019

(54) USE OF METALLIC NANO-PARTICLES, DYE-SENSITIZED SOLAR CELL AND METHOD FOR FABRICATING THE SAME

(71) Applicant: BOE TECHNOLOGY GROUP CO., LTD., Beijing (CN)

(72) Inventors: Xuefei SUN, Beijing (CN); Zhengliang LI, Beijing (CN); Bin ZHANG, Beijing (CN)

(21) Appl. No.: 16/051,550

(22) Filed: Aug. 1, 2018

(30) Foreign Application Priority Data
Aug. 4, 2017 (CN) 201710662362.0

(51) Int. Cl. H01G 9/20; H01G 9/00

(52) U.S. Cl. CPC H01G 9/2059; H01G 9/2022; H01G 9/0029; H01G 9/2036

(57) ABSTRACT

A use of metallic nano-particles, a dye-sensitized solar cell and a method for fabricating the same are disclosed. The dye-sensitized solar cell includes: an electrode; a semiconductor layer arranged on the electrode and comprising dye molecules; a metallic nano-particle layer arranged on a side of the semiconductor layer away from the electrode; and a counter electrode arranged on a side of the metallic nano-particle layer away from the semiconductor layer.

### RELATED APPLICATIONS

The present application claims the benefit of Chinese Patent Application No. 201710662362.0, filed Aug. 4, 2017, the entire disclosure of which is incorporated herein by reference.

### TECHNICAL FIELD

The present disclosure relates to the field of energy technologies, and particularly to a use of metallic nano-particles, a dye-sensitized solar cell and a method for fabricating the same.

### BACKGROUND

A dye-sensitized solar cell (DSSC) is a new generation of sustainable optoelectronic device which imitates the principle of photosynthesis in nature, absorbs sunlight by means of dye molecules, and converts light into energy. It has advantages of good thermal stability, simple fabricating process, low cost, no pollution to the environment, and nontoxicity. Thus, the dye-sensitized solar cell has been attracting the interest of the scientists since its advent. The dye-sensitized solar cell involves an ultrafast charge transfer process and an ultrathin conductive film, so that it can still operate under low light and low temperature conditions. Thus, it has a bright development future.

However, the existing dye-sensitized solar cell and a method for fabricating the same need to be improved.

### SUMMARY

In an aspect of the present disclosure, a dye-sensitized solar cell is provided. According to embodiments of the present disclosure, the dye-sensitized solar cell comprises: an electrode; a semiconductor layer comprising dye molecules on the electrode; a metallic nano-particle layer on a side of the semiconductor layer away from the electrode; and a counter electrode on a side of the metallic nano-particle layer away from the semiconductor layer.

According to embodiments of the present disclosure, the metallic nano-particle layer is made from metallic nano-particles with plasmon effect.

According to embodiments of the present disclosure, the metallic nano-particles have a diameter no less than 10 nm.

According to embodiments of the present disclosure, the metallic nano-particles comprise one or more of Ag, Al, Cu, Au, Ni, Pd, Pt, Zn and Cd.

According to embodiments of the present disclosure, the semiconductor layer comprises one or more of TiO₂, SnO₂ and ZnO.

According to embodiments of the present disclosure, the semiconductor layer has a porous structure, and the dye molecules are adsorbed in the porous structure.

According to embodiments of the present disclosure, the semiconductor layer comprises: a semiconductor sub-layer which is arranged on a side of the electrode away from the metallic nano-particle layer; and a dye molecule sub-layer which is arranged on a side of the semiconductor sub-layer away from the electrode.

According to embodiments of the present disclosure, the dye-sensitized solar cell further comprises a substrate, wherein the electrode, the semiconductor layer, the metallic nano-particle layer and the counter electrode are arranged on the substrate in this order.

In another aspect of the present disclosure, a use of metallic nano-particles for fabricating a dye-sensitized solar cell is provided. The metallic nano-particles are used to enhance the charge transfer efficiency of dye molecules. According to embodiments of the present disclosure, the metallic nano-particles are those metallic nano-particles described above.

In yet another aspect of the present disclosure, a method for fabricating a dye-sensitized solar cell is provided. According to embodiments of the present disclosure, the method comprises: preparing an electrode; forming a semiconductor layer on the electrode, wherein the semiconductor layer comprises dye molecules; forming a metallic nano-particle layer on a side of the semiconductor layer away from the electrode; and forming a counter electrode on a side of the metallic nano-particle layer away from the semiconductor layer.

According to embodiments of the present disclosure, the metallic nano-particle layer is formed by one or more of ink-jet printing, vacuum evaporation, and micro-contact printing.

According to embodiments of the present disclosure, preparing the electrode comprises: forming the electrode on a substrate.

### BRIEF DESCRIPTION OF THE DRAWINGS

To make the objects, the technical solutions and the advantages of embodiments of the present disclosure more apparent, the technical solutions of the embodiments of the present disclosure will be described in detail hereinafter in conjunction with the drawings of the embodiments of the present disclosure.

FIG. 1 is a structural view for illustrating a dye-sensitized solar cell in an embodiment of the present disclosure;

FIG. 2 is a structural view for illustrating a dye-sensitized solar cell in another embodiment of the present disclosure; and

FIG. 3 is a flow chart for illustrating a method for fabricating a dye-sensitized solar cell in an embodiment of the present disclosure.

### DETAILED DESCRIPTION OF EMBODIMENTS

The present disclosure will be described in detail hereinafter with reference to the accompanying drawings and specific implementations, for purpose of better conveying technical solutions of the present disclosure to the skilled in the art.

In description and claims of the present disclosure, direction or position relationships indicated by terms “above”, “below” or the like are based on direction or position relationships shown in the accompanying drawings, are merely used to conveniently describe the present disclosure and simplify description, and are not used to indicate or imply that the indicated device or element must have a specific direction and be constructed and operated in a specific direction. Therefore, these terms shall not be construed as limitations to the present disclosure.

The present disclosure is based on the inventors' discovering and understanding of the following facts and problems. The inventors have found that the current dye-sensitized solar cell generally suffers from a low photoelectric conversion efficiency (a photovoltaic efficiency about 10%). The inventors have found from intensive study and numerous experiments that this is primarily due to a relatively narrow linear absorption spectra of the dye molecules which act as a core component of the dye-sensitized solar cell. The dye molecules are responsible for collecting photons and separating excitons in the dye-sensitized solar cell, and the spectral absorption of dye molecules determines the photoelectric conversion efficiency of the dye-sensitized solar cell to a great extent. An upper limit of absorption spectra of the dye molecules generally does not exceed 750 nm, while 55%-60% of solar spectra is distributed in the near infrared region of 800 nm-2400 nm. Thus, the relatively narrow linear absorption spectra of the dye molecules cause a narrow spectral response range of the dye-sensitized solar cell, and the mismatch with solar spectra further causes a relatively low photoelectric conversion efficiency. This greatly hinders its process of industrialization. Besides, the low efficiency of charge transfer from the dye molecules to the semiconductor layer further causes a low photoelectric conversion efficiency of the dye-sensitized solar cell.

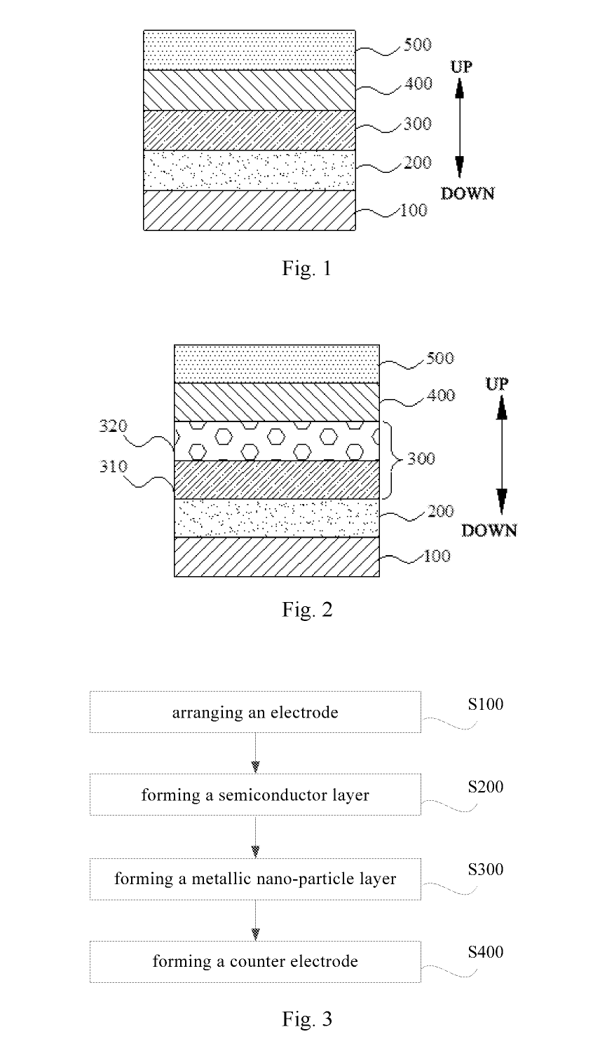

In an aspect of the present disclosure, a dye-sensitized solar cell is provided. According to embodiments of the present disclosure, as shown in FIG. 1, the dye-sensitized solar cell comprises: a substrate 100, a semiconductor layer 300, a metallic nano-particle layer 400, and a counter electrode 500. According to embodiments of the present disclosure, an electrode 200 is arranged on the substrate 100. According to embodiments of the present disclosure, the semiconductor layer 300 is arranged on a side of the electrode 200 away from the substrate 100. According to embodiments of the present disclosure, the semiconductor layer 300 comprises dye molecules. According to embodiments of the present disclosure, the metallic nano-particle layer 400 is arranged on a side of the semiconductor layer 300 away from the electrode 200. According to embodiments of the present disclosure, the counter electrode 500 is arranged on a side of the metallic nano-particle layer 400 away from the semiconductor layer 300. Thus, the arrangement of the metallic nano-particle layer 400 can greatly widen linear absorption spectra of the dye molecules. The efficiency of charge transfer from the dye molecules to the semiconductor layer 300 is enhanced, so that the photoelectric conversion efficiency of the dye-sensitized solar cell is improved.

Improving the photoelectric conversion efficiency of the dye-sensitized solar cell by arranging the metallic nano-particle layer according to embodiments of the present disclosure will be described in detail hereinafter.

As described above, the dye molecules are responsible for collecting photons and separating excitons in the dye-sensitized solar cell, and the spectral absorption of dye molecules determines the photoelectric conversion efficiency of the dye-sensitized solar cell to a great extent. Since the relatively narrow linear absorption spectra of the dye molecules causes a low photoelectric conversion efficiency of the dye-sensitized solar cell, it is required to expand the spectral response range and widen the linear absorption spectra of the dye molecules, so as to fundamentally improve the photoelectric conversion efficiency of the dye-sensitized solar cell. The inventors have found that, after a dye molecule layer (which is formed by dye molecules) is formed on the semiconductor layer, by forming a metallic nano-particle layer (which is formed by metallic nano-particles) on a side of the dye molecule layer away from semiconductor layer, the resulting metallic nano-particles have a dipole moment due to plasmon which is much larger than that of dye molecules. As a result, in a heterojunction system consisting of the metallic nano-particles, the dye molecules, and the semiconductor, the strength of coupling is greatly increased, and the excitation efficiency of the metallic nano-particles is much higher than the dye molecules. The coupling between the metallic nano-particles and the dye molecules greatly enhances the efficiency of charge transfer from the dye molecules to the semiconductor, so that the photoelectric conversion efficiency of the dye-sensitized solar cell is greatly enhanced. Namely, there is plasmon effect in the resulting metallic nano-particles. When the metallic nano-particles are excited by sunlight, the plasmon effect of metallic nano-particles can enhance the excitation efficiency of dye molecules. This greatly widens the linear absorption spectra of the dye molecules, and further enhances the light capturing capability of the dye-sensitized solar cell. Thus, the device performance of the dye-sensitized solar cell is improved, and the photoelectric conversion efficiency is enhanced. Meanwhile, the metallic nano-particles can facilitate generation of carriers, and the efficiency of charge transfer from the dye molecules to the semiconductor layer is enhanced. This facilitates improving photoelectric current and photoelectric conversion efficiency of the dye-sensitized solar cell. To sum up, the arrangement of the metallic nano-particle layer can greatly widen linear absorption spectra of the dye molecules and enhance the efficiency of charge transfer from the dye molecules to the semiconductor layer, so that the photoelectric conversion efficiency of the dye-sensitized solar cell is improved.

The structure of the dye-sensitized solar cell in specific embodiments of the present disclosure will be described in detail hereinafter.

According to embodiments of the present disclosure, the substrate 100, the electrode 200 and the counter electrode 500 are not limited regarding their features, structures, materials or properties, provided that the operational performance of the dye-sensitized solar cell is met. As appreciated by the person with ordinary skill in the art, according to embodiments of the present disclosure, the dye-sensitized solar cell can further comprise conventional layers like an electrolyte, an electron blocking layer, a hole blocking layer, to realize the operational function of the dye-sensitized solar cell, or further improve its performance. The above electrolyte, electron blocking layer, and hole blocking layer are not limited regarding their composition and form, which can be selected by the person with ordinary skill in the art as needed.

According to embodiments of the present disclosure, the semiconductor layer 300 is not limited regarding its type, provided that the operational performance of the dye-sensitized solar cell is met. For example, according to embodiments of the present disclosure, the semiconductor layer 300 can comprise at least one of TiO₂, SnO₂ and ZnO. In a specific embodiment of the present disclosure, the semiconductor layer can comprise TiO₂. Thus, the photoelectric conversion efficiency of the dye-sensitized solar cell can be further improved. According to embodiments of the present disclosure, the semiconductor layer 300 has a porous structure, and the dye molecules are adsorbed in the porous structure. In particular, the semiconductor layer 300 can be formed by at least one of TiO₂, SnO₂ and ZnO which has a nano structure. For example, it can be formed by porous nano TiO₂, or nano-rod of TiO₂, SnO₂ or ZnO. Thus, not only the adsorption efficiency of the dye molecules can be improved, but also the effective surface area of the semiconductor layer can be increased. As a result, the photoelectric conversion efficiency of the dye-sensitized solar cell can be further improved. According to embodiments of the present disclosure, the dye molecules are not limited regarding their types, provided that the operational performance of the dye-sensitized solar cell is met.

In a specific embodiment of the present disclosure, as shown in FIG. 2, the semiconductor layer 300 particularly comprises: a semiconductor sub-layer 310 and a dye molecule sub-layer 320. According to embodiments of the present disclosure, the semiconductor sub-layer 310 is arranged on a side of the electrode 200 away from the substrate 100. According to embodiments of the present disclosure, the dye molecule sub-layer 320 is arranged on the surface of the semiconductor sub-layer 310 on a side away from the electrode 200. It is noted that, the semiconductor sub-layer 310 is not limited regarding its type, provided that the operational performance of the dye-sensitized solar cell is met. For example, according to embodiments of the present disclosure, the semiconductor sub-layer 310 can be formed by at least one of TiO₂, SnO₂ and ZnO. The semiconductor sub-layer 310 can have a porous structure or nano structure as described above. In a specific embodiment of the present disclosure, the semiconductor sub-layer 310 can be TiO₂. According to embodiments of the present disclosure, the dye molecule layer 320 can be formed by the dye molecules as described above. Thus, the photoelectric conversion efficiency of the dye-sensitized solar cell can be further improved.

According to embodiments of the present disclosure, the metallic nano-particle layer 400 is made from metallic nano-particles with plasmon effect. Thus, the plasmon effect of metallic nano-particles can be made use of for greatly widening the linear absorption spectra of the dye molecules, and enhancing the efficiency of charge transfer from the dye molecules to the semiconductor layer. According to embodiments of the present disclosure, the metallic nano-particles have a diameter no less than 10 nm. For example, in a specific embodiment of the present disclosure, the metallic nano-particles can have a diameter of 15˜200 nm, or 20˜100 nm. Thus, the photoelectric conversion efficiency of the dye-sensitized solar cell can be further improved. According to embodiments of the present disclosure, the metallic nano-particles are not limited regarding their types, which can be selected by the person with ordinary skill in the art as needed. For example, according to embodiments of the present disclosure, the metallic nano-particles comprise at least one of Ag, Al, Cu, Au, Ni, Pd, Pt, Zn and Cd. In a specific embodiment of the present disclosure, the metallic nano-particles can be Au. Thus, the photoelectric conversion efficiency of the dye-sensitized solar cell can be further improved.

According to embodiments of the present disclosure, the metallic nano-particle layer 400 is arranged on a surface of the semiconductor layer 300 away from the electrode 200. Namely, during operation of the dye-sensitized solar cell, light is incident into the cell through the counter electrode. The light firstly passes through the metallic nano-particle layer 400, and induces plasmon effect. In particular, when the semiconductor layer 300 is formed by a semiconductor material of a porous or nano structure into which dye molecules are adsorbed, the metallic nano-particle layer 400 is directly arranged on the surface of the semiconductor layer 300. When the semiconductor layer 300 is formed by the semiconductor sub-layer 310 and the dye molecule sub-layer 320, the metallic nano-particle layer 400 is arranged on the surface of the dye molecule sub-layer 320.

In another aspect of the present disclosure, a use of metallic nano-particles for fabricating a dye-sensitized solar cell is provided. According to embodiments of the present disclosure, the metallic nano-particles are those metallic nano-particles as described above. According to embodiments of the present disclosure, the metallic nano-particles are used for enhancing the charge transfer efficiency of dye molecules. In particularly, after a dye molecule layer (which is formed by dye molecules) is formed on the semiconductor layer, by forming a metallic nano-particle layer (which is formed by metallic nano-particles) on a side of the dye molecule layer away from semiconductor layer, the resulting metallic nano-particles have a dipole moment due to plasmon which is much larger than that of dye molecules. As a result, in a heterojunction system consisting of the metallic nano-particles, the dye molecules, and the semiconductor, the strength of coupling is greatly increased, and the excitation efficiency of the metallic nano-particles is much higher than the dye molecules. The coupling between the metallic nano-particles and the dye molecules greatly enhances the efficiency of charge transfer from the dye molecules to the semiconductor, so that the photoelectric conversion efficiency of the dye-sensitized solar cell is greatly enhanced. Thus, the metallic nano-particle layer in the fabricated dye-sensitized solar cell can improve the photoelectric conversion efficiency.

In yet another aspect of the present disclosure, a method for fabricating a dye-sensitized solar cell is provided. According to embodiments of the present disclosure, the dye-sensitized solar cell can be the dye-sensitized solar cell as described above. As shown in FIG. 3, the method comprises the following steps.

S100: arranging an electrode.

According to embodiments of the present disclosure, in this step, an electrode is arranged on a substrate. According to embodiments of the present disclosure, there is no limit to the manner in which the electrode is arranged, provided that the operational performance of the dye-sensitized solar cell is met. According to embodiments of the present disclosure, the substrate and the electrode are not limited regarding their features, structures, materials or properties, provided that the operational performance of the dye-sensitized solar cell is met.

S200: forming a semiconductor layer.

According to embodiments of the present disclosure, in this step, a semiconductor layer is formed on a side of the electrode away from the substrate. The semiconductor layer comprises dye molecules. According to embodiments of the present disclosure, there is no limit to the manner in which the semiconductor layer is formed, provided that the operational performance of the dye-sensitized solar cell is met. According to embodiments of the present disclosure, the semiconductor layer is not limited regarding its type, provided that the operational performance of the dye-sensitized solar cell is met. For example, according to embodiments of the present disclosure, the semiconductor layer comprises at least one of TiO₂, SnO₂ and ZnO. In a specific embodiment of the present disclosure, the semiconductor layer can comprise TiO₂. Thus, the photoelectric conversion efficiency of the dye-sensitized solar cell can be further improved. According to embodiments of the present disclosure, the semiconductor layer has a porous structure, and the dye molecules are adsorbed in the porous structure. Thus, the photoelectric conversion efficiency of the dye-sensitized solar cell can be further improved. According to embodiments of the present disclosure, the dye molecules are not limited regarding their types, provided that the operational performance of the dye-sensitized solar cell is met.

According to embodiments of the present disclosure, the resulting semiconductor layer particularly comprises a semiconductor sub-layer and a dye molecule sub-layer. According to embodiments of the present disclosure, the semiconductor sub-layer can be formed on a side of the electrode away from the substrate, and then a dye molecule layer is formed on a side of the semiconductor sub-layer away from the electrode. According to embodiments of the present disclosure, features, structures, materials or properties of the semiconductor sub-layer and dye molecule layer have been described above, and thus are not repeated here.

S300: forming a metallic nano-particle layer.

According to embodiments of the present disclosure, in this step, a metallic nano-particle layer is arranged on a side of semiconductor layer away from electrode. According to embodiments of the present disclosure, there is no limit to the manner in which the metallic nano-layer is formed, provided that the requirements for form the metallic nano-layer are met. For example, according to embodiments of the present disclosure, the metallic nano-particle layer is formed by at least one of ink-jet printing, vacuum evaporation, and micro-contact printing. Thus, the metallic nano-particle layer can be fabricated in a simple manner. The photoelectric conversion efficiency of the fabricated dye-sensitized solar cell can be further improved. According to embodiments of the present disclosure, forming the metallic nano-layer by ink-jet printing can comprise: coating a dispersion in which metallic nano-particles are dissolved on the dye molecule layer at preset positions; forming the metallic nano-layer by vacuum evaporation can comprise: forming the metallic nano-particle layer by using a mask; and forming the metallic nano-layer by micro-contact printing can comprise: transferring a pre-fabricated metallic nano-particle layer onto dye molecule layer.

According to embodiments of the present disclosure, the metallic nano-particle layer is made from metallic nano-particles with plasmon effect. Thus, the plasmon effect of metallic nano-particles can be made use of for greatly widening the linear absorption spectra of the dye molecules, and enhancing the efficiency of charge transfer from the dye molecules to the semiconductor layer. According to embodiments of the present disclosure, the metallic nano-particles have a diameter no less than 10 nm. Thus, the photoelectric conversion efficiency of the dye-sensitized solar cell can be further improved. According to embodiments of the present disclosure, the metallic nano-particles are not limited regarding their types, which can be selected by the person with ordinary skill in the art as needed. For example, according to embodiments of the present disclosure, the metallic nano-particles comprise at least one of Ag, Al, Cu, Au, Ni, Pd, Pt, Zn and Cd. In a specific embodiment of the present disclosure, the metallic nano-particles can be Au. Thus, the photoelectric conversion efficiency of the dye-sensitized solar cell can be further improved.

S400: forming a counter electrode.

According to embodiments of the present disclosure, in this step, a counter electrode is arranged on a side of metallic nano-particle layer away from semiconductor layer. According to embodiments of the present disclosure, there is no limit to the manner in which the counter electrode is arranged, provided that the operational performance of the dye-sensitized solar cell is met. According to embodiments of the present disclosure, the counter electrode is not limited regarding its feature, structure, material or property, provided that the operational performance of the dye-sensitized solar cell is met.

According to embodiments of the present disclosure, after the above steps, the dye-sensitized solar cell is subsequently fabricated by conventional processes.

To sum up, the method can fabricate the dye-sensitized solar cell in a simple manner. In the fabricated dye-sensitized solar cell, the resulting metallic nano-particle layer can greatly widen linear absorption spectra of the dye molecules, and the efficiency of charge transfer from the dye molecules to the semiconductor layer is enhanced, so that the photoelectric conversion efficiency of the fabricated dye-sensitized solar cell is improved.

The technical solutions of the present disclosure will be explained with reference to the following embodiments. As understood by the person with ordinary skill in the art, the following embodiments are only used for explaining the present disclosure, and do not limit the scope of the present disclosure in any way. Techniques or conditions which have not been clearly specified in the embodiments follow techniques or conditions as described in the literature in the art, or follow the product specification. Reagents or instruments of which the manufacturers are not specified are conventional products which are commercially available.

According to an embodiment of the present disclosure, first, the electrode, the semiconductor sub-layer, and the dye molecule layer are formed on the substrate in this order. Then, a dispersion in which metallic nano-particles are dissolved is coated on the dye molecule layer at preset positions, i.e., the metallic nano-layer is formed by ink-jet printing. The semiconductor sub-layer is TiO₂. The metallic nano-particles are Au with a radius of 10 nm. The counter electrode is FTO, i.e., SnO₂ doped with F. Thus, the dye-sensitized solar cell with the metallic nano-particle layer is formed.

In a comparative example, the fabricated dye-sensitized solar cell differs from the above embodiment in that, after forming the dye molecule layer, the metallic nano-particle layer is not formed.

Simulation tests are performed on the amount of charge transfer in the dye-sensitized solar cells which are fabricated according to the above embodiment and the comparative example. Au ion has a dipole moment d=2893 D (Debye), and the dye molecules have a dipole moment d=8 D. Under excitation of a light field of 1000 KV/m, the amount of charge transfer from the dye molecules to the semiconductor in the comparative example is 3.82×10⁻⁷. Under excitation of the same light field (1000 KV/m), in the above embodiment, the strength of coupling between the metallic nano-particles and the dye molecules is 86 meV, and the amount of charge transfer from the dye molecules to the semiconductor is 1.81×10⁻².

It is known from the above tests that in the dye-sensitized solar cell according to the embodiment of the present disclosure, the charge transfer efficiency is increased by about a factor of 4.74×10⁴. This shows that the introduction of the metallic nano-particle layer can greatly enhance the photoelectric conversion efficiency of the dye-sensitized solar cell.

For example, the words “first”, “second” as well as similar words used in the patent application specification and claims of the present invention do not mean any sequence, quantity or importance, but are only used to distinguish different components. The term such as “comprises,” “comprising,” “comprises,” “comprising”, “contains” or the like means that an element or article prior to this term encompasses element(s) or article(s) listed behind this term and equivalents, but does not preclude the presence of other elements or articles. The terms indicating orientations or position relationships such as “one side”, “the other side” or the like which are based on the orientation or position relationship illustrated in the attaching drawings, and are only for facilitating and simplifying the description of the present disclosure, rather than meaning or implying that the mentioned apparatus or element must have a specific orientation or must be constructed or operate in a specific orientation, and therefore should not be understood as limitations to the present disclosure.

Apparently, the person with ordinary skill in the art can make various modifications and variations to the present disclosure without departing from the spirit and the scope of the present disclosure. In this way, provided that these modifications and variations of the present disclosure belong to the scopes of the claims of the present disclosure and the equivalent technologies thereof, the present disclosure also intends to encompass these modifications and variations.

What is claimed is:

1. A dye-sensitized solar cell, comprising:
an electrode;
a semiconductor layer comprising dye molecules on the electrode;
a metallic nano-particle layer on a side of the semiconductor layer away from the electrode; and
a counter electrode on a side of the metallic nano-particle layer away from the semiconductor layer.

2. The dye-sensitized solar cell of claim 1, wherein the metallic nano-particle layer is made from metallic nano-particles with plasmon effect.

3. The dye-sensitized solar cell of claim 2, wherein the metallic nano-particles have a diameter no less than 10 nm.

4. The dye-sensitized solar cell of claim 2, wherein the metallic nano-particles comprise one or more of Ag, Al, Cu, Au, Ni, Pd, Pt, Zn and Cd.

5. The dye-sensitized solar cell of claim 1, wherein the semiconductor layer comprises one or more of TiO₂, SnO₂ and ZnO.

6. The dye-sensitized solar cell of claim 5, wherein the semiconductor layer has a porous structure, and the dye molecules are adsorbed in the porous structure.

7. The dye-sensitized solar cell of claim 1, wherein the semiconductor layer comprises:
a semiconductor sub-layer which is arranged on a side of the electrode away from the metallic nano-particle layer; and
a dye molecule sub-layer which is arranged on a side of the semiconductor sub-layer away from the electrode.

8. The dye-sensitized solar cell of claim 1, further comprises a substrate, wherein the electrode, the semiconductor layer, the metallic nano-particle layer and the counter electrode are arranged on the substrate in this order.

9. A use of metallic nano-particles for fabricating the dye-sensitized solar cell of claim 1.

10. A method for fabricating a dye-sensitized solar cell, comprising:
preparing an electrode;
forming a semiconductor layer on the electrode, wherein the semiconductor layer comprises dye molecules;
forming a metallic nano-particle layer on a side of the semiconductor layer away from the electrode; and
forming a counter electrode on a side of the metallic nano-particle layer away from the semiconductor layer.

11. The method of claim 10, wherein the metallic nano-particle layer is formed by one or more of ink-jet printing, vacuum evaporation, and micro-contact printing.

12. The method of claim 10, wherein preparing the electrode comprises: forming the electrode on a substrate.
